(19) United States
(12) Patent Application Publication
(10) Pub. No.: US 2002/0176226 A1
(43) Pub. Date: Nov. 28, 2002

(54) Elongate component supported by support component separate from circuit boards

(76) Inventors: Regenia Ann Richardson, Aurora, IL (US); William Harold Scofield, Batavia, IL (US)

Correspondence Address: GROSSMAN, PATTI & BRILL, 300 W. WASHINGTON ST. #1200, CHICAGO, IL, 60606-2002, US

(21) Appl. No.: 10/073,746

(22) Filed: Feb. 11, 2002

Related U.S. Application Data
(63) Continuation-in-part of application No. 09/567,517, filed on May 9, 2000, now Pat. No. 6,359,782.

(51) Int. Cl. H05K 7/20

(52) U.S. Cl. 361/689; 361/690; 361/720

(57) ABSTRACT

An elongate component of an apparatus is positioned generally transverse to a general direction of a forced air stream, upstream from at least one electrical component, and spaced apart from and extended over a portion of a circuit board such that removal of thermal energy emitted from the at least one electrical component results. The forced air stream is provided in the general direction to flow over the circuit board and toward the at least one electrical component located on the circuit board. The circuit board is located proximate to zero or more additional circuit boards. The elongate component is supported by a support component separate from the circuit board and the zero or more additional circuit boards. Turbulence is added to the forced air stream to increase the amount of air contacting the at least one electrical component through employment of the elongate component.

### CROSS-REFERENCE TO RELATED APPLICATION

This application is a continuation-in-part of commonly-owned U.S. patent application Ser. No. 09/567,517 (by William Harold Scofield, filed May 9, 2000, and entitled “ENHANCED THERMAL DISSIPATION DEVICE FOR CIRCUIT BOARDS AND METHOD TO USE THE SAME”), which is hereby incorporated herein by reference in its entirety.

### TECHNICAL FIELD

This invention relates generally to a device that removes thermal build-up generated from the operation of electrical components on a circuit board and more particularly, to the removal of thermal build-up from the operation of electrical components on a circuit board utilizing a forced air stream.

### BACKGROUND

It is known that energized electrical components positioned on a circuit board generate a significant amount of heat. In most industries, such as the telecommunications industry, there is a need to place higher output electronic devices on already congested circuit boards. Higher clock speed and higher density interconnects lead inevitably to higher power densities on a chip. The resultant byproducts of the high output devices are high levels of thermal dissipation from the chip or component and the immediately surrounding atmosphere to the component. These high levels of thermal energy being dissipated to the immediate surrounding environment are problematic to maintaining effective operation and optimum life of surrounding electrical components.

Higher output devices are known to utilize an increased number of multi-chip modules, increased surface circuit board mounting technology such as mezzanine boards, and reduced package dimensions all of which exacerbate the problem of the undesirable thermal build-up from the thermal dissipation of energized electrical components residing on the circuit board(s). With power per unit area on circuit boards as much as quadrupling over less than the past decade, thermal design issues have arisen that as recently as five years ago were not even comprehended or contemplated.

As mentioned above, a contributing problem to thermal build-up is the utilization of mezzanine arranged or stacked circuit boards. The increased use of mezzanine boards has come about with the increase of clock speeds and shorter lead traces, the circuit designers have needed to shorten the electrical path between components enabling quicker response time of the electronics. The negative side of these arrangements is there is an increase of power density from the electrical components on the circuit boards thereby releasing heat energy in a relatively smaller area. Therefore, there is an increasing need to remove this thermal energy away from the proximity of the electrical components and not allow the dissipated energy to build-up on localized areas of the circuit boards and the surrounding electrical components. Failure to remove the undesirable thermal build-up can place the die of an integrated circuit component at critical elevated temperatures that either temporarily or permanently damage the components.

Another problem has been created with the closer positioning of the circuit boards to one another in a stacked or mezzanine arrangement. This problem is based on radiation energy generated from high-energy dies on a circuit board. Normally a circuit board with a centralized die will experience lower temperatures at the edges of the circuit board and greater temperatures at the location of the die. Radiation may be a major heat transfer mechanism for outer space applications but is generally negligible where the circuit board is positioned in a forced air convection system. However, with closer positioning of the components within a mezzanine arrangement of circuit boards, radiation of energy from these high energy components will further lead to thermal build-up.

Moreover, these compact circuit arrangements pose yet additional problems. Regardless of the components being positioned within a forced air stream, the tight arrangements of the components increases the air stream flow resistance thereby blocking the air flow and reducing its thermal dissipation capabilities based on convection from the forced air stream.

As a result of utilizing higher energy components that are more densely arranged upon a circuit board and positioning multiple circuit boards in closer proximity to one another, thermal build-up has become a problem, regardless of the use of forced air streams flowing over the circuit boards.

### SUMMARY

The invention in one embodiment encompasses an apparatus. A forced air stream is provided in a general direction to flow over a circuit board and toward at least one electrical component located on the circuit board. The circuit board is located proximate to zero or more additional circuit boards. An elongate component is positioned generally transverse to the general direction of the forced air stream, upstream from the at least one electrical component, and spaced apart from and extended over a portion of the circuit board such that removal of thermal energy emitted from the at least one electrical component results. The elongate component is supported by a support component separate from the circuit board and the zero or more additional circuit boards.

Another embodiment of the invention encompasses a method. A forced air stream is provided in a general direction to flow over a circuit board and toward at least one electrical component located on the circuit board. The circuit board is located proximate to zero or more additional circuit boards. Turbulence is added to the forced air stream to increase the amount of air contacting the at least one electrical component through employment of an elongate component supported by a support component separate from the circuit board and the zero or more additional circuit boards.

### DESCRIPTION OF THE DRAWINGS

Features of exemplary implementations of the invention will become apparent from the description, the claims, and the accompanying drawings in which:

FIG. 1 is a perspective view of the invention;

FIG. 2 is a side elevation view of the invention as seen along line 112 in FIG. 1;

FIG. 3 is a front elevation view of the invention as seen along line 114 in FIG. 1;

FIG. 4 is an enlarged cross section view as seen along 116 in FIG. 1;

FIG. 5 is a front elevation view of another embodiment of the invention;

FIG. 6 is a front elevation view of another embodiment of the invention;

FIG. 7 is a front elevation view of another embodiment of the invention;

FIG. 8 is a perspective view of the invention with a mezzanine circuit board arrangement; and

FIG. 9 is a front elevation view as seen along line 816 in FIG. 8.

FIG. 10 is a cutaway, sectional, partial, front representation of an exemplary implementation of elongate components supported by support components separate from circuit boards in a chassis, illustrating forced air streams provided in a general direction to flow over the circuit boards.

FIG. 11 is a cutaway, sectional, partial, top representation of the elongate components supported by the support components separate from the circuit boards in the chassis of FIG. 10.

FIG. 12 is a cutaway, sectional, partial, front representation of a number of the elongate components supported by a number of the support components separate from the circuit boards of FIG. 10, illustrating a number of the forced air streams provided in the general direction.

### DETAILED DESCRIPTION

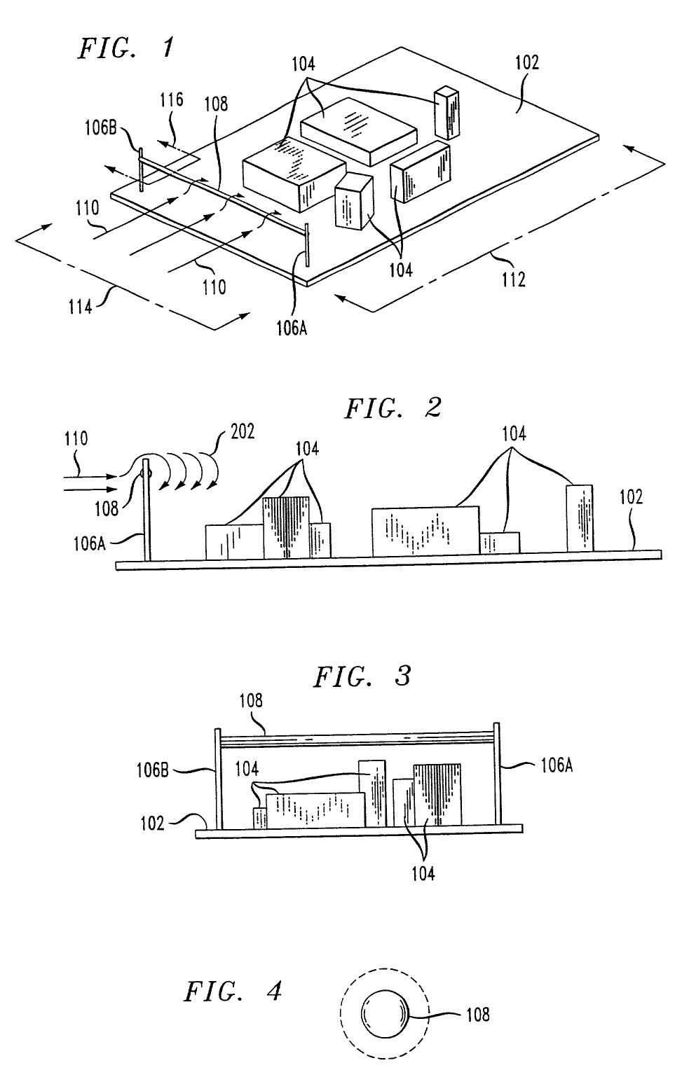

Referring to FIG. 1, a perspective view of a circuit board 102 shows a number of electrical components 104 coupled to the circuit board 102. Two securement members 106A and 106B, shown as posts, are secured to the circuit board 102 and secure rod 108 spaced apart from a plane defined by the circuit board 102 and position it generally parallel to circuit board 102. A forced air stream 110 flows over the circuit board 102 and toward the electrical components 104. Rod 108 has an elongated dimension between the support members 106A and 106B. The elongated dimension of the rod 108 is positioned transverse to the forced air stream 110 and results in an increased turbulent air flow. Additionally, the rod 108 has a circular cross section that creates vortices in the turbulent air flow.

Two smooth cylinder rod examples of ⅛″ and ¼″ diameter were utilized in tests and will be discussed, with the understanding that other diameters of the cylindrical obstruction to laminar air flow are alternate embodiments of this invention. Moreover, other shapes of rods are also contemplated.

The velocity of the free air stream flow can be used to determine the drag force, caused by the cylinder rod obstructing the forced air stream flow, as well as the frequency of the shedding vortices in the wake field downstream from the rod. The net force of the air stream flow on the cylinder rod is the drag force aligned with the flow direction. The drag force and the wake property, momentum thickness, hold an important relationship thus enabling a calculation of the drag from the momentum thickness. The drag force is a combination of both pressure and frictional forces. The relative contributions of the friction drag force however decrease with increasing Reynolds number (Re). At Re≈1000 the friction drag is about 5% of the total drag. The Reynolds number is defined as stated in Equation:

$$Re = \frac{ρ {μ}_{0} d}{μ}$$

Where:

ρ=density of air;

μ₀=free stream flow velocity

d=cross sectional diameter of the object at right angles to the flow; and

μ=fluid kinematic viscosity.

If the forced air stream is considered to be incompressible (valid because the flow speed is less than 0.3 Mach) and viscous, the viscous forces in the boundary layer acts to retard the flow. The flow velocity reduces to zero at a stagnation point. Energy of the forced air stream is conserved; therefore a decrease in velocity is accompanied by the increase in pressure at the stagnation point. The pressure differential causes the forced air stream along the boundary of the obstruction to increase in velocity causing a reduction in pressure. The pressure difference is the main contributor to the drag force for flow in the range of:

10³<Re<3×10⁵

The formation of a boundary layer reduces the flow and causes a reduction in the momentum flux. The momentum thickness (θ) is defined as the thickness of a layer of fluid (forced air) with a specific velocity for which the momentum flux is equal to the deficit of momentum flux through the boundary layer. This is an integral thickness defined in Equation 2 below and will be used to determine the calculated drag forces on the cylinder rod.

$$θ = d {\int }_{- ∞}^{∞} [ \frac{{u}_{w}}{{u}_{0}} - {( \frac{{u}_{w}}{{u}_{0}} )}^{2} ] ⅆ ( \frac{y}{d} )$$

Where:

θ=momentum thickness;

d=cylinder diameter;

u₀=free stream velocity;

u_{w}=wake velocity; and

y=vertical displacement.

The drag force is calculated theoretically from the equation for drag force:

$${F}_{D} = {C}_{D} A ρ \frac{{u}_{0}^{2}}{2}$$

Where:

F_{D}=drag force;

C_{D}=coefficient of drag;

A=projected area of a cylinder perpendicular to the forced air stream;

ρ=density of air; and

u₀=free stream flow velocity.

Or the drag force can be calculated theoretically from the momentum thickness of the wake:

F_{D}=ρu₀²θw

Where:

F_{D}=drag force;

θ=momentum thickness

w=width of the surface perpendicular to flow;

ρ=density of air; and

u₀=free stream flow velocity.

The Strouhal number (St) is a nondimensionalized number that relates the frequency of oscillation to the free stream velocity and the cylinder diameter. The equation below is used to determine the frequency of shedding vortices that form downstream from the cylinder rod:

$$St ≡ \frac{fd}{{u}_{0}}$$

Where:

St=Strouhal number;

ƒ=frequency of oscillation; and

u₀=free stream flow velocity.

Thus the fundamental characteristics of a cylinder rod in an air stream flow include drag force, velocity profile, and shedding frequency for the forced air stream across a cylinder rod and are determinable. Furthermore, the turbulent air flow that is created by the cylinder rod results in vortices that allow more cool air to interact with the surfaces of the electrical components 104 on the circuit board 102.

In FIG. 2, a side elevation view of the invention as seen along line 112 of the circuit board 102, FIG. 1, is shown. The circuit board 102 has a plurality of electrical components 104 and post 106A can be seen. Posts 106A and 106B are spaced apart to one another and are positioned proximate to and secured to an edge of circuit board 102 upstream from electrical components 104. The cross section of rod 108 is identifiable as being circular in shape. The rod is in the path of the forced air stream 110 and when encountered by the forced air stream 110 a turbulent air stream 202 results. The turbulent air stream 202 contacts the circuit board and electrical components more efficiently with imparting a vertical component to the air flow relative to the plane of the circuit board than if a laminar air flow passing over the circuit board resulting in greater heat transfer and longer electrical component life. It is often desired to position rod 108 at a sufficient elevation over circuit board 102 so as to be above electrical components 104 to optimize the effect of the turbulent air flow.

In FIG. 3, a front elevation view as seen along line 114 of the circuit board 102, FIG. 1, is shown. The two posts 106A and 106B are spaced apart with rod 108 positioned between the two posts and likewise secured to the posts. Rod 108 is supported by the two post 106A and 106B and secured thereto by any number of ways such as gluing, providing a snap fit or utilizing any other known securement. Rod 108 is positioned and is secured to the posts 106A and 106B at a height above the electrical components 104. The height of the rod 108 enables the vortices of the turbulent air stream to flow over and around the electrical components coupled to the circuit board resulting in more efficient cooling than a traditional laminar air stream.

Turning to FIG. 4, an enlarged cross section view of rod 108 as seen along 116 in FIG. 1 is shown. Rod 108 in the current embodiment is a wire, but in alternate embodiments other cylindrical material may be used, such as fiberglass rod, metal rods, plastic, or any other material that create a turbulent air stream. Rod 108 is round in the current embodiment, but in other embodiments other shapes may selectively be used.

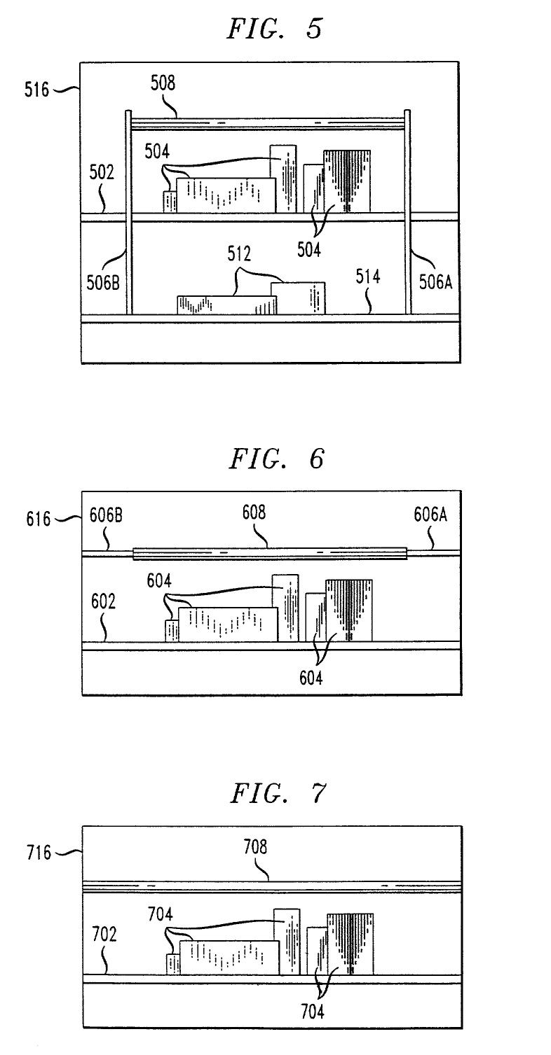

In FIG. 5, a front elevation view of another embodiment of the invention is shown. A circuit board 502 with electronic components 504 is positioned and held in a housing 506. The circuit board 502 in housing 516 is spaced apart from another circuit board 514 with other electrical components 512 secured thereto. The other circuit board 508 has two support members 506A and 506B that are spaced apart and of sufficient height to support rod 508 above electrical components 504 on the circuit board 502.

In FIG. 6, a front elevation view of another embodiment of the invention is shown. A housing 616 containing a printed circuit board 602 with electrical components 604 secured thereto. Housing 616 has two supports 606A and 606B for supporting a rod 608 above electrical components 604 and in the forced air stream.

Turning to FIG. 7, a front elevation view of another embodiment of the invention is shown. Circuit board 702 having electrical components 704 is contained within housing 716. Housing 716 also supports rod 708 that is secured directly to the walls of the housing 716. In an alternate embodiment rod 708 is integral with housing 716. Rod 708 is positioned in the present embodiment above the electronic components, such that the laminar air flow becomes a turbulent air flow upon contact with the rod 708. Once again, rod 708 is secured to housing 706 utilizing numerous securements such as being integral, glued or supported by an opening in housing 716 as well as or other common ways of securement.

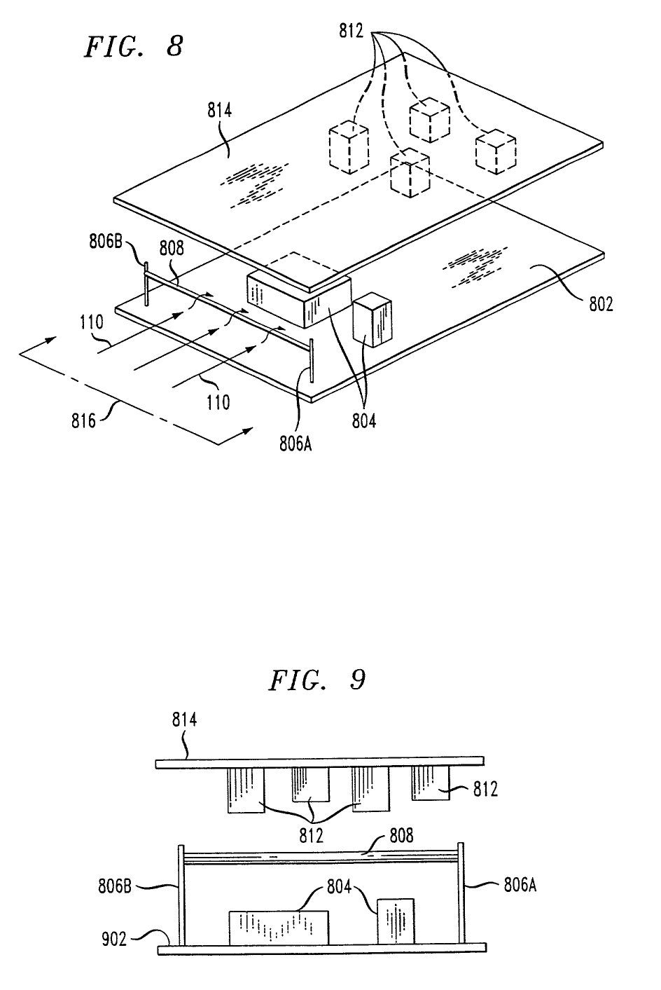

In FIG. 8, a perspective view of the invention with a mezzanine circuit board arrangement of a first circuit board 802 with electrical components 804 and a second circuit board 814 with other electrical components 812 secured thereto. The second circuit board 814 overlies the first circuit board 802 creating a mezzanine circuit board arrangement. Rod 808 is in the upstream path of the forced air stream 110 from the electrical components 804 and other electrical components 812 and is spaced apart from planes defined by first circuit board 802 and second circuit board 814. Rod 808 is supported in the present embodiment by two support members 806A and 806B. Rod 808 may be supported by numerous ways as discussed previously. In this example, the support members 806A and 806B are coupled to first circuit board 802. As laminar air encounters rod 808, it is disrupted and becomes a turbulent forced air stream. The turbulent forced air stream has vortices of rotating air that has a vertical component relative to the plane defined by the circuit boards 802, 814 and results in more efficient cooling of the electrical components on both circuit boards 802 and 814.

Circuit boards 802 and 814 in a mezzanine arrangement have a velocity boundary layer that greatly affects the fluid velocity (air velocity). When fluid particles make contact with a surface, they assume zero velocity. These particles then act to retard the motion of the particles in the adjoining fluid layer, which act to retard the motion of the particles in the next boundary layer, and so on until, at a distance from the surface, the effects becomes negligible. This effect becomes even more dramatic when the flow is between two parallel plates, as in the mezzanine arrangement. In this case the boundary layer thickness associated with each plate comes into contact with the other. In the case of gases, the Prandt1 number is Pr≈1. Because the boundary layers come in contact they are prevented from growing. This is unfortunate because fully developed turbulent flow is significantly increased when the boundary layer thickness increases. In the fully developed region highly random three-dimensional motion of relatively large parcels of fluid move freely within the boundary layer that increases the heat transfer from the surface to the free stream fluid. However, the fluid in the compacted boundary layer can be forced to a turbulent state.

For example, the fluid flow can be modified by the introduction of a cylindrical rod. The rod placed in the cross flow will cause the flow in its wake to shed vortices at regular frequency. The shedding vortices increase the random three-dimensional motion and thus improve the transfer of heat. The Nusselt number is a dimensionless parameter describing the radiant at the surface and provides a measure of the convection heat transfer occurring at the surface. The Nusselt number is a function of the Prandtl and Reynolds numbers. The Reynolds number is strongly effected by the fluid velocity and hence the design of the system in which the mezzanine arrangement will be used. For laminar flow the Nusselt number is:

Nᵤ≡0.664Re^{1/2}Pr^{1/3}

Where Re was given by the Reynolds equation and Pr is 0.707 for air at sea level.

While for turbulent flow the Nusselt number is:

Nᵤ≡0.137Re^{4/5}Pr^{1/3}

Where Re was given by the Reynolds equation and Pr is 0.707 for air at sea level.

Therefore heat transfer rate is calculated by the equation:

$$h = \frac{{N}_{u} k}{L}$$

Where:

h=heat transfer coefficient,

Nu=Nusselt number,

k=fluid thermal conductivity and;

L=length of the plate

The heat transferred from the circuit board to the free flowing fluid can be calculated by the equation:

q=hA(T_{S}−T_{∞})

Where:

q=heat transfer,

h=heat transfer coefficient,

A=surface area

T_{S}=surface temperature and;

T_{∞}=fluid free stream temperature.

Now for a given set of conditions we can compare the amount of heat transferred in laminar and turbulent conditions. Let A=1 {m²}, (Tₛ−T_{∞})=40, Re=10,000, k=0.0364 {W/mK}, and L=0.1 {m}, then using the above equations:

For laminar conditions q=861 Watts.

For turbulent conditions q=2816 Watts

Therefore, more heat is transferred to the environment, lowering the temperature of the mezzanine arrangement of circuit boards 802, 814 and increasing the life of the electrical components 804, 812.

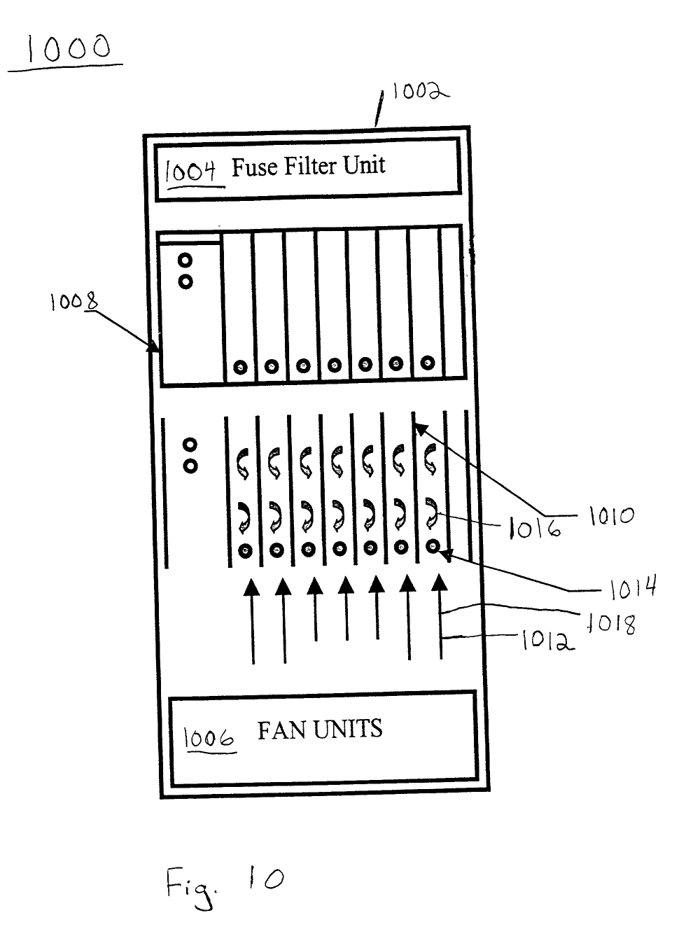

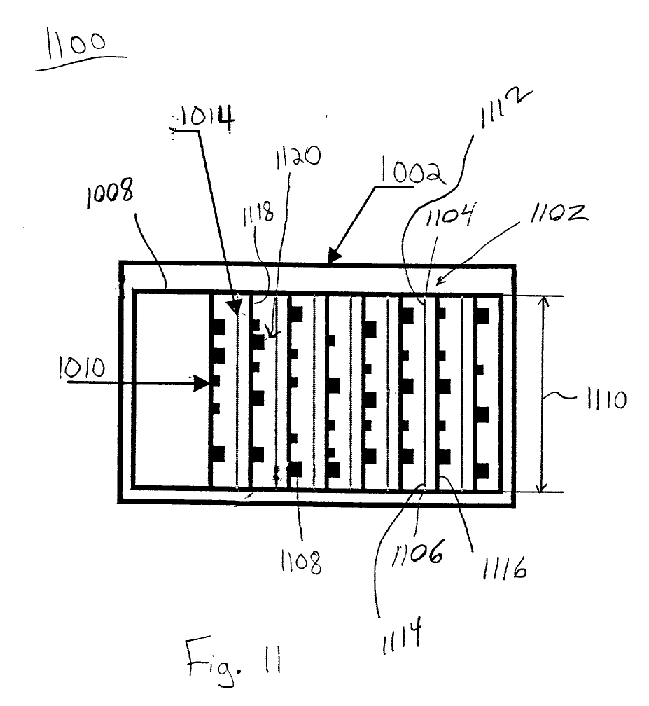

In FIG. 9, a front elevation view of the mezzanine circuit board arrangement as seen along line 816 in FIG. 8 is shown. First circuit board 802 with electrical components 804 extends towards second circuit board 814. Similarly, the other electrical components 812 on second circuit board 814 extend towards the first circuit board 802. Rod 808 is secured to posts 806A and 806B (securement members) and placed upstream from all of electrical components 804, 812. Thus laminar air flow becomes turbulent upon contacting and interacting with rod 808.

The present invention includes providing a method for removal of thermal energy emitted by at least one electrical component 104 positioned on circuit board 102 in which a forced air stream 110 is provided and directed to flow over circuit board 102 and toward the at least one electrical component 104. The method includes providing rod 108 having an elongated dimension and positioning rod 108 in forced air stream 110 with the elongated dimension transverse to the direction of forced air stream 110 and upstream to the at least one electrical component 104, as seen in FIGS. 1 and 2.

Even though other shapes of rods are contemplated, the step of providing includes selecting rod 108 having a circular cross section. In the step of positioning is included placing rod 108 generally parallel to a plane defined by circuit board 102, as well as, positioning rod 108 at an elevation above the elevation of the at least one electrical component 104 which extends above circuit board 102.

The step of positioning rod 808 in forced air stream 110 with elongated dimension transverse to the direction of forced air stream 110 and upstream to another of at least one electrical component 812 positioned on another circuit board 814, as seen in FIGS. 8 and 9, and spaced apart from another plane defined by other circuit board 814. The step of positioning also includes placing rod 808 between two planes defined by circuit boards 802 and 814.

In addition, a step of orienting involves circuit board 802 and other circuit board 814 to have at least one electrical component 104 positioned on circuit board 802 extending in a direction toward the other circuit board 814 and the other at least one electrical component 812 positioned on the other circuit board 814 extending in a direction toward circuit board 802, as seen in FIGS. 8 and 9.

Turning to FIG. 10, an apparatus 1000 in one example comprises an elongate component positioned generally transverse to a general direction of a forced air stream, upstream from at least one electrical component, and spaced apart from and extended over a portion of a circuit board such that removal of thermal energy emitted from the at least one electrical component results. The forced air stream is provided in the general direction to flow over the circuit board and toward the at least one electrical component located on the circuit board. The circuit board is located proximate to zero or more additional circuit boards. The elongate component is supported by a support component separate from the circuit board and the zero or more additional circuit boards. Turbulence is added to the forced air stream to increase the amount of air contacting the at least one electrical component through employment of the elongate component. As will be appreciated by those skilled in the art, a portion of a component of the apparatus 1000 in one example comprises all of the component, and in another example comprises a subportion of the component, where the subportion of the component comprises less than all of the component.

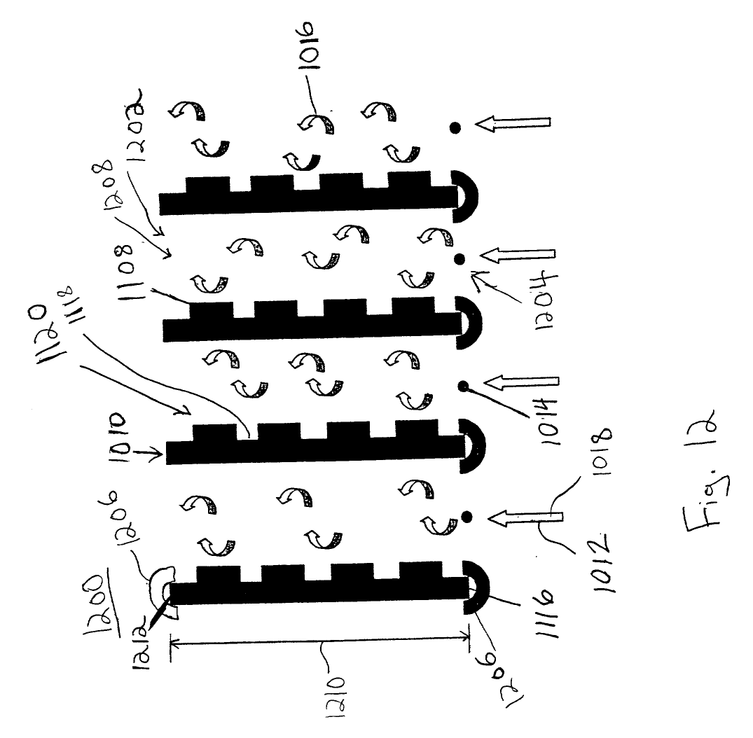

Referring to FIGS. 10-11, in one example, an apparatus 1000 comprises a chassis 1002, a fuse filter unit 1004 one or more fan units 1006, one or more shelves 1008, one or more circuit boards 1010, one or more elongate components 1014, and one or more support components 1102. The apparatus 1000 in one example comprises any (e.g. horizontal, oblique, or vertical) orientation, with the description and figures herein illustrating one exemplary orientation of the apparatus 1000 for explanatory purposes.

Referring to FIG. 10, the chassis 1002 in one example comprises a structural framework that serves to support the fuse filter unit 1004, the fan units 1006, and the one or more shelves 1008. The fuse filter unit 1004 in one example serves to filter (e.g., undesired) electrical noise in the chassis 1002. In a further example, the fuse filter unit 1004 provides fused electrical connections for electrical equipment in the chassis 1002. For example, electrical connections from the circuit boards 1010 are connected with the fuse filter unit 1004. In addition, the fan units 1006 in one example serve to create one or more forced air streams 1012 that flow in a general direction 1018 over the one or more circuit boards 1010, as described herein.

Referring to FIGS. 11-12, the shelves 1008 serve to support the support components 1102 and a plurality of card guides 1206. The support components 1102 are connected with (e.g. attached to) the shelves 1008. In one example, the support components 1102 are mechanically mounted on and/or fixed to the shelves 1008. In another example, the support components 1102 and the shelves 1008 comprise a unitary construction. For example, the support components 1102 and the shelves 1008 are formed integrally.

Again referring to FIGS. 11-12, the shelves 1008, in one example, serve to provide gaps 1202 between the card guides 1206 supporting the circuit boards 1010. The gaps 1202, in one example, comprise gaps 1204 and 1208. The forced air stream 1012 enters the shelf 1008 at gap 1204, flows across the circuit boards 1010, and then exits the shelf 1008 from gap 1208 as will be appreciated by those skilled in the art.

Still referring to FIGS. 11-12, the card guides 1206 serve to support the circuit boards 1010. A pair of the card guides 1206, in one example, serve to support the circuit board 1010. For example, one of the card guides 1206 receives edge 1116 of the circuit board 1010 and the other of the card guides 1206 receives edge 1212 of the circuit board 1010. The card guides 1206 in one example are connected with (e.g. attached to) the shelf 1008. In one example, the card guides 1206 and the shelf 1008 comprise non-unitary construction. In another example, the card guides 1206 and the shelf 1008 comprise unitary construction. The card guides 1206 in one example are arranged to receive and/or support the circuit boards 1010 in a side-by-side relationship. In a further example, card guides 1206 allow for insertion and/or removal of the circuit boards 1010.

Referring to FIG. 12, the circuit board 1010 in one example comprises a card and/or a printed circuit board (“PCB”). The circuit board 1010 in one example comprises a base 1118 and a face 1120. In one example, the one or more electrical components 1108 are connected with (e.g. attached to) the base 1118 of the circuit board 1010. For example, the electrical components 1108 are soldered to the circuit board 1010. The electrical components 1108 in one example comprise integrated circuit (“IC”) components, as will be appreciated by those skilled in the art. In one example, the electrical components 1108 comprise a portion of the face 1120 of the circuit board 1010.

Referring to FIGS. 11-12, the circuit board 1010 comprises dimensions 1110 and 1210. In one example, dimension 1110 is longer than dimension 1210. In another example, dimension 1210 is longer than dimension 1110. In yet another example, dimensions 1110 and 1210 are of substantially the same length.

Referring to FIG. 11, in one example there is one circuit board 1010 in the shelf 1008. In another example, each of the circuit boards 1010 is arranged in the shelf 1008 in a side-by-side relationship with at least one other of the circuit boards 1010. So the circuit board 1010, in one example, is located proximate to zero or more additional circuit boards 1010.

Referring to FIGS. 11-12, the support components 1102 in one example serve to support the elongate component 1014. In one example, the support component suspends the elongate component 1014 in the forced air stream 1012, for example, substantially perpendicular to the general direction 1018 of the forced air stream 1012. In another example, the support components 1102 comprise a first support subportion 1104 and a second support subportion 1106. For example, the first support subportion 1104 is connected with subpart 1112 of the elongate component 1014, and the second support subportion 1106 is connected with subpart 1114 of the elongate component 1014.

Referring to FIG. 11, in one example, the support components 1102 and the elongate component 1014 comprise non-unitary constructions. For example, glue or welding is employed to connect the support components 1102 and the elongate component 1014. In another example, the support components 1102 and the elongate component 1014 comprise a unitary construction. For example, the support component 1102 and elongate component 1014 are formed integrally. In a further example, the elongate component 1014, the support component 1102, and the shelf 1008 comprise a unitary construction (e.g., are formed integrally).

Referring to FIGS. 10-11, the support components 1102 in one example are located proximate to an edge 1116 of the circuit board 1010 and upstream of the electrical components 1108, relative to the general direction 1018 of flow of the forced air stream 1012. The support components 1102 are a portion of the shelf 1008 that is separate from the circuit boards 1010. For example, the support components 1102 and the circuit board 1010 comprise non-unitary constructions.

Referring to FIG. 11, the elongate component 1014 extends over the circuit board 1010 in the dimension 1110. In one example, the elongate component 1014 extends over an entire dimension of the face 1120 of the circuit board 1010. The elongate component 1014 and the base 1118 of the circuit board 1010 comprise a generally uniform space therebetween. For example, the distance between the elongate component 1014 and the base 1120 of the circuit board 1010 is substantially the same over the dimension 1110 of the elongate component 1014. In one example, there is modest variation in the distance between the elongate component 1014 and the base 1120 of the circuit board 1010 over the dimension 1110. In another example, there is little, if any, variation in the distance between the elongate component 1014 and the base 1120 of the circuit board 1010 over the dimension 1110.

Referring to FIG. 12, the elongate component 1014 is located a distance further above the face 1120 of the circuit board 1010 than any of the electrical components 1108. In one example, the elongate component 1014 is located a distance further outward from a base 1118 of the circuit board 1010. The elongate component 1014 is located proximate to the edge 1116 of the circuit board 1010 and upstream of the forced air stream 1012 relative to the circuit board 1010. In one example, the forced air stream 1012 will pass the elongate component 1014 prior to reaching the circuit board 1010 as described herein.

Still referring to FIG. 12, the elongate component 1014 in one example comprises any of a plurality of materials. In one example, the elongate component 1014 comprises plastic, copper, steel, tin, or gold. The elongate component 1014 in one example comprises any of a plurality of shapes. In one example, the elongate component 1014 comprises a rod. In another example, the elongate component 1014 comprises a wire with a circular cross-section. In a further example, the elongate component 1014 comprises any of a rectangular, triangular, ovular, or trapezoidal shape.

Referring to FIGS. 10 and. 12, the fan units 1006 serve to cause the forced air stream 1012 to flow in the general direction 1018 over the circuit board 1010 and toward the one or more electrical components 1108. In one example, the forced air stream 1012 serves to dissipate heat from the electrical components 1108. In another example, the forced air stream 1012 uses forced convection techniques to dissipate heat in electrical components 1108. For example, the air in the forced air stream 1012 that comes into contact with electrical components 1108 serve to remove heat from the electrical components 1108. In another example, increasing the amount of air from the forced air stream 1012 contacting the electrical components 1108 serves to increase the amount of heat dissipated from the electrical components 1108.

Referring to FIG. 12, the elongate component 1014 is positioned transversely to the general direction 1018 of the forced air stream 1012. In one example, the elongate component 1014 comprises an orientation that is crosswise to the forced air stream 1012 yet located within the forced air stream 1012. Positioning the elongate component 1014 in the forced air stream 1012 increases the amount of a turbulence 1016 in the forced air stream 1012 and serves to increase the heat dissipated from the electrical components 1108. In one example, the elongate component 1014 disturbs the forced air stream 1012, causing more air from the forced air stream 1012 to contact the electrical components 1108 and serves to dissipate more heat from the electrical components 1108. In another example, the forced air stream 1012 passing the elongate component 1014 causes a shedding of vortices, as will be appreciated by those skilled in the art, forcing more air from the forced air stream 1012 to contact electrical components 1108, and serving to dissipate more heat from the electrical components 1108. In a further example, positioning the elongate component 1014 in the forced air stream 1012 results in more effective cooling of the electrical components 1108 as opposed to using the forced air stream 1012 without the elongate component 1014.

Referring to FIGS. 10-12, in one example, the elongate components 1014 are supported without occupying space on the circuit board 1010. In a further example, the elongate components 1014 are supported with little or no hindrance of thermal dissipation from the electrical components 1108.

The steps or operations described herein are just exemplary. There may be many variations to these steps or operations without departing from the spirit of the invention. For instance, the steps may be performed in a differing order, or steps may be added, deleted, or modified.

Although exemplary implementations of the invention have been depicted and described in detail herein, it will be apparent to those skilled in the relevant art that various modifications, additions, substitutions, and the like can be made without departing from the spirit of the invention and these are therefore considered to be within the scope of the invention as defined in the following claims.

What is claimed is:

1. An apparatus, wherein a forced air stream is provided in a general direction to flow over a circuit board and toward at least one electrical component located on the circuit board, wherein the circuit board is located proximate to zero or more additional circuit boards, the apparatus comprising:
an elongate component positioned generally transverse to the general direction of the forced air stream, upstream from the at least one electrical component, and spaced apart from and extended over a portion of the circuit board such that removal of thermal energy emitted from the at least one electrical component results; and
wherein the elongate component is supported by a support component separate from the circuit board and the zero or more additional circuit boards.

2. The apparatus of claim 1 in combination with the support component, wherein the support component and circuit board comprise non-unitary constructions.

3. The apparatus of claim 2, wherein the support component comprises a portion of a shelf, wherein the shelf serves to the elongate component and one or more card guides that server to support the circuit board.

4. The apparatus of claim 1, wherein the elongate component comprises a generally circular cross-section.

5. The apparatus of claim 4, wherein the elongate component comprises a rod.

6. The apparatus of claim 1 in combination with the support component, wherein the support component comprises a first support subportion and a second support subportion, wherein the elongate component comprises a wire or a filament having a first subpart connected with the first subportion and a second subpart connected with the second portion.

7. The apparatus of claim 1 in combination with the support component, wherein the elongate component and the support component comprise a unitary construction.

8. The apparatus of claim 1 in combination with the support component, wherein the support component serves to suspend the elongate component within the forced air stream.

9. The apparatus of claim 1, wherein the at least one electrical component comprises a plurality of electrical components located on the circuit board, wherein the elongate component is located proximate to an edge of the circuit board and upstream of the plurality of electrical components.

10. The apparatus of claim 9 in combination with the support component, wherein the support component is located proximate to the edge of the circuit board and upstream of the plurality of electrical components.

11. The apparatus of claim 1, wherein the elongate component extends over an entire dimension of a face of the circuit board, wherein the at least one electrical component comprises a portion of the face on the circuit board.

12. The apparatus of claim 1, wherein the elongate component and a base of the circuit board comprise a generally uniform spacing therebetween.

13. The apparatus of claim 12, wherein the at least one electrical component comprises a portion of the circuit board, wherein the elongate component is located a distance further outward from the base of the circuit board than any of the at least one electrical component.

14. A method, wherein a forced air stream is provided in a general direction to flow over a circuit board and toward at least one electrical component located on the circuit board, wherein the circuit board is located proximate to zero or more additional circuit boards, comprising the step of:
adding turbulence to the forced air stream to increase the amount of air contacting the at least one electrical component through employment of an elongate component supported by a support component separate from the circuit board and the zero or more additional circuit boards.

15. The method of claim 14, wherein the step of adding the turbulence comprises the step of:
employing the turbulence to promote an increase in heat dissipation from the at least one electrical component.
